(19) United States
(12) Patent Application Publication
(10) Pub. No.: US 2025/0029813 A1
(43) Pub. Date: Jan. 23, 2025

(54) METHOD AND APPARATUS FOR HEATING A MEDIUM USING AN RF SIGNAL

(71) Applicant: TRUMPF Huettinger GmbH + Co. KG, Freiburg (DE)

(72) Inventors: Sebastian Wassenberg, Oberderdingen (DE); Thomas Traber, Strasslach- Dinghartingen (DE)

(21) Appl. No.: 18/660,351

(22) Filed: May 10, 2024

Related U.S. Application Data
(63) Continuation of application No. PCT/EP2022/081638, filed on Nov. 11, 2022.

(30) Foreign Application Priority Data
Nov. 12, 2021 (DE) 10 2021 129 565.3

(51) Int. Cl. H01J 37/32

(52) U.S. Cl. CPC H01J 37/32174

(57) ABSTRACT

A method for heating a medium includes generating a first radio-frequency (RF) feed signal having a first operating frequency, incoupling the first RF feed signal into the medium so as to heat the medium, determining a first RF signal reflection, and changing the first operating frequency based on the first RF signal reflection. During a first test interval, the first operating frequency is increased. During a second test interval, the first operating frequency is reduced. The method further includes determining a second RF signal during the first test interval, determining a third RF signal reflection during the second test interval, after the second test interval has elapsed, generating a second RF feed signal with a second operating frequency, and incoupling the second RF feed signal into the medium. The second operating frequency is selected based on the first, the second, and the third RF signal reflections.

### CROSS REFERENCE TO RELATED APPLICATIONS

This application is a continuation of International Application No. PCT/EP2022/081638 (WO 2023/084033 A1), filed on Nov. 11, 2022, and claims benefit to German Patent Application No. DE 10 2021 129 565.3, filed on Nov. 12, 2021. The aforementioned applications are hereby incorporated by reference herein.

### FIELD

Embodiments of the present invention relate to a method for heating a medium, in particular for generating a plasma, using an RF signal.

Embodiments of the invention also relate to an apparatus for heating a medium, in particular for generating a plasma, using an RF signal.

### BACKGROUND

A method and a corresponding apparatus are known for example from US 2014/0197761 A1.

The known apparatus can be used inter alia to generate a plasma which serves for the surface processing of workpieces in etching and/or coating installations. Plasma is understood here to be a gas which is brought to an excited state by energy absorption (heating) from outside, such that charge carriers of the gas are released from their respective atomic and/or molecular bonds and present as free charge carriers. Consequently, the plasma has an electrical conductivity that is dependent on the number of free charge carriers and thus on the respective energy absorption. What is characteristic of an apparatus for generating a plasma is that the impedance of the load, i.e. in this case the impedance of the plasma chamber to be supplied with the heating energy, can change very rapidly and significantly. This places stringent demands on the RF generator that generates the electrical RF signal for heating the gas and for supplying the plasma with electrical power, and on the transmission path, since the incoupling of the electrical heating signal is dependent on how well the output impedance of the generator is matched to the input impedance of the load. Any mismatch leads to reflections with the consequence that a portion or, in the worst case, even the whole of the electrical power fails to reach the gas or plasma to be heated, but rather is reflected to the output of the generator. Without suitable countermeasures, this can lead to the destruction of the generator and/or other components of such an apparatus. Moreover, the plasma may be quenched if not enough heating power reaches the gas any more.

The known methods for adapting the operating frequency of an RF signal generator used for heating a medium are comparatively complex in their implementation. Moreover, searching for the respective optimum operating frequency requires rather a long time in some implementations.

### SUMMARY

Embodiments of the present invention provide a method for heating a medium to generate a plasma. The method includes generating a first radio-frequency (RF) feed signal having a defined first operating frequency and a defined first signal power, incoupling the first RF feed signal into the medium via a transmission path, so that the medium is heated by the first RF feed signal, determining a first RF signal reflection along the transmission path, and changing the first operating frequency based on the first RF signal reflection in order to reduce temporally succeeding RF signal reflections. During a first test interval, the defined first operating frequency is increased by a defined first frequency value in order to incouple the first RF feed signal into the medium in a temporally limited manner with an increased first operating frequency. During a second test interval, the defined first operating frequency is reduced by a defined second frequency value in order to incouple the first RF feed signal into the medium in a temporally limited manner with a reduced first operating frequency. The method further includes determining a second RF signal reflection temporally correlating with the increased first operating frequency during the first test interval, determining a third RF signal reflection temporally correlating with the reduced first operating frequency during the second test interval, after the second test interval has elapsed, generating a second RF feed signal with a defined second operating frequency, and incoupling the second RF feed signal into the medium. The defined second operating frequency is selected based on the first RF signal reflection, the second RF signal reflection, and the third RF signal reflection.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a simplified schematic illustration of a first exemplary embodiment of an apparatus;

FIG. 2 shows a simplified schematic illustration of a second exemplary embodiment of an apparatus; and

FIG. 3 shows a flow diagram for explaining one exemplary embodiment of a method.

### DETAILED DESCRIPTION

Embodiments of the present invention provide a method and an apparatus which enable a suitable operating frequency of the RF signal generator to be set relatively simply and rapidly.

Embodiments of the present invention provide a method for heating a medium, in particular for generating a plasma, using an RF signal, comprising the following steps:
generating an RF feed signal having a defined first operating frequency and a defined first signal power, in particular by means of an RF generator,
incoupling the RF feed signal into the medium via a transmission path, such that the medium is heated by the RF feed signal,
determining a first RF signal reflection along the transmission path, in particular by means of a measuring and control device, and
changing the first operating frequency in a manner dependent on the first RF signal reflection in order to reduce temporally succeeding RF signal reflections, in particular by means of the measuring and control device.

Embodiments of the present invention also provide an apparatus for heating a medium, in particular for generating a plasma, using an RF signal,
comprising an RF generator configured to generate an RF feed signal having a defined first operating frequency and a defined first signal power,
comprising a transmission path configured to incouple the RF feed signal into the medium, such that the medium can be heated by the RF feed signal, and
comprising a measuring and control device configured to determine a first RF signal reflection along the transmission path, and
furthermore configured to change the first operating frequency in a manner dependent on the first RF signal reflection in order to reduce temporally succeeding RF signal reflections.

The present invention is not restricted to apparatuses and methods for generating a plasma, even though this is a preferred application. The described method and the described apparatus can equally also be used for heating other media and/or for other purposes, for instance for heating liquid or solid media.

According to some embodiments, during a first test interval the defined first operating frequency is changed, in particular increased, by a defined first frequency value in order to incouple the first RF feed signal into the medium in a temporally limited manner with a changed, in particular increased, first operating frequency, and wherein during a second test interval the defined first operating frequency is oppositely changed, in particular reduced, by a defined second frequency value in order to incouple the first RF feed signal into the medium in a temporally limited manner with an oppositely changed, in particular reduced, first operating frequency, wherein a second RF signal reflection temporally correlating with the changed, in particular increased, first operating frequency is determined during the first test interval, and wherein a third RF signal reflection temporally correlating with the oppositely changed, in particular reduced, first operating frequency is determined during the second test interval, and wherein after the second test interval has elapsed, the RF feed signal is generated with a defined second operating frequency and is incoupled into the medium, wherein the defined second operating frequency is selected in a manner dependent on the first, second and third RF signal reflections, in particular from the first operating frequency, the oppositely changed, in particular reduced, first operating frequency and the changed, in particular increased, first operating frequency.

In accordance with a further aspect, this object is achieved by an apparatus of the type mentioned in the introduction, wherein the measuring and control device is furthermore configured to change, in particular to increase, the defined first operating frequency by a defined first frequency value during a first test interval in order to incouple the first RF feed signal into the medium in a temporally limited manner with a changed, in particular increased, first operating frequency, furthermore oppositely to change, in particular to reduce, the defined first operating frequency by a defined second frequency value during a second test interval in order to incouple the first RF feed signal into the medium in a temporally limited manner with an oppositely changed, in particular reduced, first operating frequency, furthermore during the first test interval to determine a second RF signal reflection temporally correlating with the changed, in particular increased, first operating frequency, furthermore during the second test interval to determine a third RF signal reflection temporally correlating with the oppositely changed, in particular reduced, first operating frequency, and after the second test interval has elapsed, to generate the RF feed signal with a defined second operating frequency and to incouple it into the medium, wherein the defined second operating frequency is selected in a manner dependent on the first, second and third RF signal reflections, in particular from the first operating frequency, the changed, in particular increased, first operating frequency and the oppositely changed, in particular reduced, first operating frequency.

The described apparatus and the described method can be implemented very simply, particularly if the RF signal generator is a so-called solid state generator with a voltage-controlled oscillator (VCO) and/or a phase locked loop (PLL). Such an RF signal generator allows the instantaneous operating frequency to be changed simply and rapidly. In some preferred exemplary embodiments, the RF signal generator generates the RF feed signal with an operating frequency that is in the lower microwave range, in particular in the range of 2 GHz to 5 GHz. In one exemplary embodiment, the first operating frequency is in the range of 2.4 GHz to 2.5 GHz, in each case inclusive.

Proceeding from an instantaneous first operating frequency, which in some exemplary embodiments can be a nominal operating frequency selected beforehand, the described apparatus and the described method test an increased first operating frequency and a reduced first operating frequency in two temporally successive test intervals while the RF feed signal continues to be incoupled into the medium. The temporal order of the first and second test intervals is freely selectable, in principle. That means that, in some exemplary embodiments, the defined first operating frequency can firstly be increased and be reduced at a later time. In other exemplary embodiments, by contrast, the defined first operating frequency can firstly be reduced and be increased at a later time. Accordingly, the designations first test interval and second test interval here do not imply a mandatory temporal order. To put it another way, the second test interval can temporally precede the first test interval.

In any case the instantaneous operating frequency of the RF feed signal is increased at least once and reduced at least once in a test cycle. In preferred exemplary embodiments, the instantaneous operating frequency is increased exactly once and, at a preceding time or at a succeeding time, reduced exactly once in a test cycle. Associated or assignable RF signal reflections along the transmission path are determined for each of the three operating frequencies thus obtained (instantaneous first operating frequency, increased first operating frequency and reduced first operating frequency). At least three characteristic values for RF signal reflections are thus present after such a test. Advantageously, in a very simple manner, that operating frequency from the (three) stated operating frequencies which correlates with the smallest RF signal reflection of the at least three detected RF signal reflections is then selected for the further operation of the RF signal generator.

It is possible for the (future) second operating frequency to be determined and selected very simply and rapidly in this way. In particular, the described method can be implemented straightforwardly and very advantageously in the firmware of an RF signal generator with a controllable operating frequency. Accordingly, in preferred exemplary embodiments of the described apparatus, the increasing and reducing of the respective operating frequency in temporally limited test intervals are implemented in the firmware of a processor-controlled RF signal generator. As an alternative thereto, in other exemplary embodiments, the increasing and reducing of the first operating frequency could be effected “externally”, i.e. could be initiated by way of a control signal supplied to the RF signal generator externally.

The described method and the described apparatus have the advantage that, firstly, the search for a “better” operating frequency is restricted to a small instantaneous search range. In the preferred exemplary embodiments, the search for a “better” operating frequency is restricted to exactly two alternative values, namely one above and one below the instantaneous operating frequency. This search can therefore proceed very rapidly. Secondly, the described method and the described apparatus involve searching “on two sides” for an operating frequency that is possibly better than the instantaneous first operating frequency. Therefore, the described method and the described apparatus can follow dynamically varying impedance changes rapidly and direction-independently, i.e. both toward higher impedances and toward lower impedances.

The described method and the described apparatus afford a new possibility of very simply and rapidly setting a suitable operating frequency for the RF signal generator. The object mentioned above is therefore achieved in its entirety.

In one preferred embodiment of the invention, the increasing and reducing of the respective operating frequency are repeated cyclically with respective further test intervals, wherein the defined second operating frequency is used as a new first operating frequency after each cycle.

In this configuration, the described method and the described apparatus follow dynamically varying impedance changes of the load to be heated during ongoing operation of the RF signal generator. The present operating frequency in each case is adaptively and dynamically adapted to varying impedances. Permanently very efficient feeding of the heating power into the medium is thus achieved.

In a further configuration, the increasing and reducing of the respective operating frequency are carried out cyclically with a cycle time T which is in a range of 1 ms to 500 ms, in each case inclusive.

In preferred exemplary environments, these values have proved to be very well suited to managing dynamically varying impedances for a plasma load, without a lasting influence on the generation of the plasma by the respective operating frequency being increased and reduced for test purposes.

In a further configuration, the first test interval has an interval length which is in a range of 50 μs to 500 μs, in each case inclusive.

In preferred exemplary embodiments, these values have also proved to be very well suited to managing dynamically varying impedances for a plasma load, with the plasma at the same time being maintained by constant supply of power.

In a further configuration, the defined first operating frequency is increased abruptly by the defined first frequency value at the beginning of the first test interval. Advantageously, the defined first operating frequency is reduced abruptly at the beginning of the second test interval.

Abruptly increasing or reducing the first operating frequency in each case enables very short test intervals and, in association therewith, a rapid and accurate assignment of the respective RF signal reflections. Alternatively, in other configurations, the increasing or reducing of the first operating frequency could take place with a non-abrupt and hence rather smooth transition, which in some scenarios can have the advantage that the plasma excitation is more stable. In many cases, however, the abrupt increasing or reducing appears to be more advantageous owing to the minimal test time.

In a further configuration, the defined first frequency value and the defined second frequency value are equal.

In this configuration, the first operating frequency is in the middle between the increased first operating frequency and the reduced first operating frequency. The configuration has the advantage that the instantaneous operating frequency of the RF signal generator remains largely constant on average over time across the test intervals, which likewise advantageously contributes to keeping the plasma excitation stable.

In a further configuration, the defined first frequency value is in a range of 0.0001% to 0.001% of the defined first operating frequency. In some exemplary embodiments, the defined first frequency value can by way of example be in the range of 5 kHz to 20 kHz, in each case inclusive. In one advantageous exemplary embodiment, the first frequency value is 10 kHz at an operating frequency of the RF signal generator in the region of 2.45 GHz.

A first frequency value in the ten-thousandths range relative to the nominal operating frequency of the RF signal generator is very advantageous in order firstly to ensure that the plasma generation is stable, and secondly to react to impedance changes of the plasma load in a targeted manner.

In a further configuration, the second test interval is directly adjacent to the first test interval.

In this configuration, the second test interval directly precedes the first test interval or it directly follows the first test interval. This has the consequence that the instantaneous operating frequency of the RF signal generator after a temporally limited increase (reduction) is set as rapidly as possible to the opposite frequency value below (above) the original first operating frequency. In an exemplary embodiment in which the first frequency value and the second frequency value are equal, the operating frequency of the RF signal generator remains very close to the original first operating frequency on average over time across the two test intervals. In exemplary embodiments in which the defined first operating frequency is increased abruptly by the defined first frequency value at the beginning of the first test interval and is reduced abruptly at the beginning of the second test interval, the instantaneous operating frequency thus jumps by double the frequency value upon the transition from the first test interval to the second test interval (or vice versa). The configuration advantageously contributes to keeping the plasma excitation very stable across the test intervals.

In a further configuration, the defined first operating frequency is determined by an RF test signal with an instantaneous operating frequency that passes through a defined frequency band being transmitted via the transmission path, RF signal reflections along the transmission path being determined.

In this configuration, the first operating frequency, forming as it were the start value of the described method, is determined in a targeted search pass over the defined frequency band. As an alternative thereto, the RF signal generator could initially “start” with a nominal operating frequency or an operating frequency selected in some other way. In some exemplary embodiments, the defined frequency band includes the total bandwidth made available by the RF signal generator in a defined operating mode. Alternatively or supplementarily, the frequency band can be defined on the basis of legal and/or official stipulations and include in particular all frequencies which are expedient and/or approved for the desired operation and/or the heating of the desired medium. In some exemplary embodiments, the defined frequency band covers a frequency range which is included in a range of 2% to 6%, in each case inclusive, of the defined operating frequency, i.e. e.g. at a defined operating frequency of 2.45 GHz in a range of approximately 50 MHz to 150 MHz, in each case inclusive.

The configuration supplements the above-described method as it were by a “global scan”, i.e. a previous and/or interim search for an optimum operating frequency over the defined frequency band. The configuration very advantageously contributes to finding the best operating frequency over the available frequency band simply and as rapidly as possible.

In a further configuration, the RF test signal is generated separately from the RF feed signal and transmitted via the transmission path. Advantageously, in some variants of this configuration, the RF test signal can be transmitted via the transmission path in addition to, i.e. temporally in parallel with, the RF feed signal. As an alternative thereto, in other exemplary embodiments, the RF test signal can be transmitted via the transmission path in a manner temporally separated from the RF feed signal.

The configuration makes it possible to test the signal reflections independently of the RF feed signal and thus largely independently of the heating of the medium across a large frequency range. This configuration therefore makes possible a high degree of flexibility, which is advantageous if very different media are intended to be heated by the RF signal generator. The configuration also includes the possibility of using the RF test signal as a modulation signal for the RF feed signal and in this way combining it with the RF feed signal.

In a further configuration, the RF feed signal forms the RF test signal.

In this configuration, the RF feed signal is used for a test scan over the defined frequency band. This makes possible a very cost-effective realization.

In a further configuration, the RF test signal is generated at a time before the first test interval.

In this configuration, the “global scan” is performed before or at the beginning of heating in order to obtain an initial optimum operating frequency as a starting point of the described method. The configuration is quite simple to implement and makes possible an optimum operating frequency already at the beginning of the described method.

In a further configuration, the RF test signal is generated again after the second test interval has elapsed.

In this configuration, the “global scan” is also performed repeatedly once or more than once after the beginning of heating, i.e, thus during heating. The configuration contributes to obtaining an optimum operating frequency in each case even when there are very great changes in the load impedance.

It goes without saying that the abovementioned features and the features yet to be explained below are usable not only in the respectively specified combination but also in other combinations or on their own, without departing from the scope of the present invention.

Exemplary embodiments of the invention are illustrated in the drawing and are explained in more detail in the description that follows.

The descriptions of similar methods and/or apparatuses cited below also serve for better categorization in the technical environment and the exemplary embodiments:

US 2014/0197761 A1, cited in the introduction, describes an apparatus comprising a plurality of material processing assemblies connected to an RF signal generator in parallel with one another. The material processing assemblies may be for example chambers for plasma-assisted coating of workpieces (PVD or PACVD chambers). US 2014/0197761 A1 discloses that each material processing assembly has a measuring device used to measure the reflected power in each case. In a manner dependent on the reflected powers measured in each case, the operating frequency of the RF feed signal is then intended to be varied until one or two differently defined threshold values are reached for all the material processing assemblies. US 2014/0197761 A1 discloses in this context that the frequency of the RF feed signal influences the reflected power, and describes a total of six different operating modes in which the frequency and/or power of the RF feed signal are/is varied until the defined threshold values are reached.

US 2009/0237170 A1 discloses a method and an apparatus for generating a plasma using an RF signal, wherein the operating frequency of the RF signal generator is varied in a manner dependent on impedance changes of the plasma load and reflections resulting therefrom. Here the intention is to search for the optimum operating frequency of the RF signal generator by virtue of the overall available bandwidth of the generator being subdivided into sixteen sub-bands. During operation, the RF signal generator is intended to operate at its chosen operating frequency for 99% of the time. In the remaining 1% of the time, the intention is to check in the sixteen sub-bands in turn, for a short time in each case, to establish whether there is a more suitable operating frequency.

DE 10 2011 076 404 B4 describes a method for matching the output impedance of a radio-frequency power supply arrangement to the impedance of a plasma load. The operating frequency of the RF signal generator is monitored as to whether it is in a predefined frequency range. Matching is achieved by mechanical and/or electrical alteration of a circuit connected downstream of the RF signal generator.

A white paper from TRUMPF Hüttinger GmbH+Co. KG at 79111 Freiburg in Germany entitled “A New Auto Frequency Tuning Algorithm” from July 2015 discloses that the RF feed signal of an RF generator for a plasma load is constantly provided with a frequency modulation in order to find the best operating frequency in each case during operation.

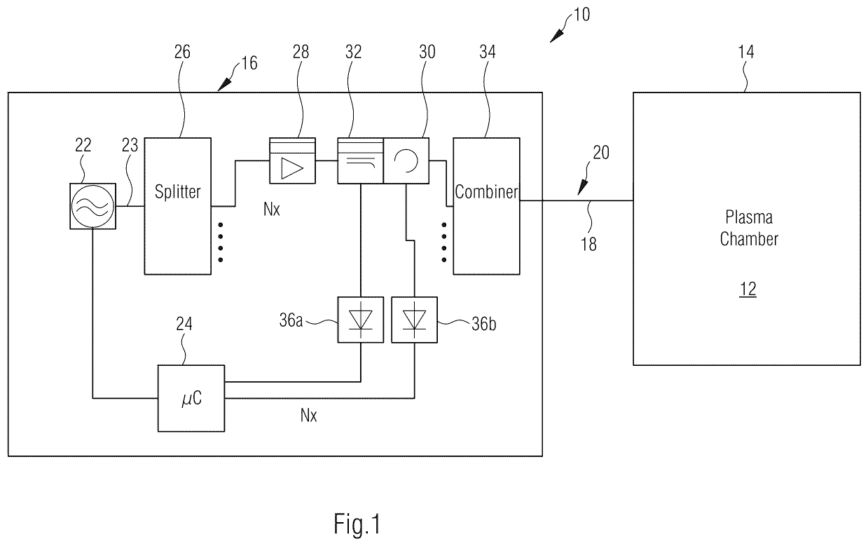

One exemplary embodiment of the described apparatus is designated by the reference numeral 10 in FIG. 1. The apparatus 10 here serves for heating a gaseous medium 12 in a plasma chamber 14, in which for example workpieces (not illustrated here) are intended to be etched and/or coated with the aid of a plasma. In principle, however, the described method and the described apparatus can also be used for heating solid and/or liquid media, as is sufficiently known for routine domestic microwave cooking appliances.

The apparatus 10 has an RF signal generator 16, which generates an RF feed signal 18 and incouples it into the medium 12 via a transmission path 20. In the simplest case, electrodes (not illustrated here) are arranged in the plasma chamber 14, the RF feed signal 18 e.g. in the form of an electromagnetic wave being incoupled into the medium 12 via said electrodes.

In this exemplary embodiment, the RF signal generator 16 has a voltage-controlled oscillator 22 (VCO), which is controlled by way of a microprocessor 24 (μC) and generates a radio-frequency signal 23 having an operating frequency which is dependent on the control voltage obtained from the microprocessor 24. As an alternative or in addition to the microprocessor 24, the RF signal generator 16 can have a microcontroller and/or some other control circuit, such as, for instance, one or more ASICs, FPGAs or the like. In some exemplary embodiments, the operating frequency can be in a range of 2.4 GHz to 2.5 GHz.

The radio-frequency signal 23 here is supplied to a splitter 26, which splits the radio-frequency signal 23 among a plurality of parallel signal paths Nx, which is indicated by vertically arranged dots in FIG. 1. Only a single signal path is illustrated here, for reasons of clarity. In the preferred exemplary embodiments, the parallel signal paths Nx are each constructed identically and have the same elements. In particular, each of the parallel signal paths Nx contains a signal amplifier 28, which amplifies the corresponding signal component of the radio-frequency signal 23 in the signal path Nx. Furthermore, here each of the parallel signal paths Nx contains a circulator 30 and a directional coupler 32, disposed upstream of the circulator 30 here in the forward direction with respect to the plasma chamber 14.

The signal components of the radio-frequency signal 23 that have been respectively amplified in the parallel signal paths Nx are combined here by a coupler 34 (combiner). Preferably, the amplified signal components of the radio-frequency signal 23 are combined in the correct phase relation in the combiner 34. The coupler 34 (combiner) thus generates the powerful RF feed signal 18 from the individually amplified signal components of the radio-frequency signal 23. The splitting of the radio-frequency signal 23 among parallel signal paths Nx each having at least one signal amplifier 28 and the subsequent combination in the combiner 34 facilitate a high power amplification of the original radio-frequency signal 23 in preferred exemplary embodiments. In principle, however, the described method and the corresponding apparatus can also be realized with a single signal amplification path.

The directional coupler 32 in each signal path Nx is configured here, in a manner known per se, to outcouple a small signal component of the RF signal 18 passing toward the plasma chamber 14 and to supply it to the microprocessor 24 via a rectifier 36a. The circulator 30 in each signal path Nx is configured here to guide away a signal reflection (typically in the form of a returning wave, not illustrated here). In the exemplary embodiment illustrated here, the circulator 30 in each signal path Nx, for measurement purposes, guides a small portion of the returning signal reflection via a further rectifier 36b to the microprocessor 24.

The circulator 30 in each signal path Nx serves here firstly to keep the returning signal reflection away from the amplifier 27, the oscillator 22 and other sensitive components of the RF signal generator 16. Furthermore, the circulator 30 in each signal path Nx here also acts in a similar manner to the directional coupler 32 by virtue of the fact that it supplies a small portion of the returning signal reflection to the microprocessor 24 for measurement purposes.

In preferred exemplary embodiments, the microprocessor 24 can include one or more analog-to-digital converters (not illustrated here) or can be combined with one or more analog-to-digital converters connected upstream (not illustrated here). The analog-to-digital converter(s) is/are advantageously configured to convert the signal components of the outgoing power that are outcoupled via the directional couplers 32, and the returning power guided away by the circulator 30, into digital values and thus to make them available for digital signal processing in the microprocessor 24.

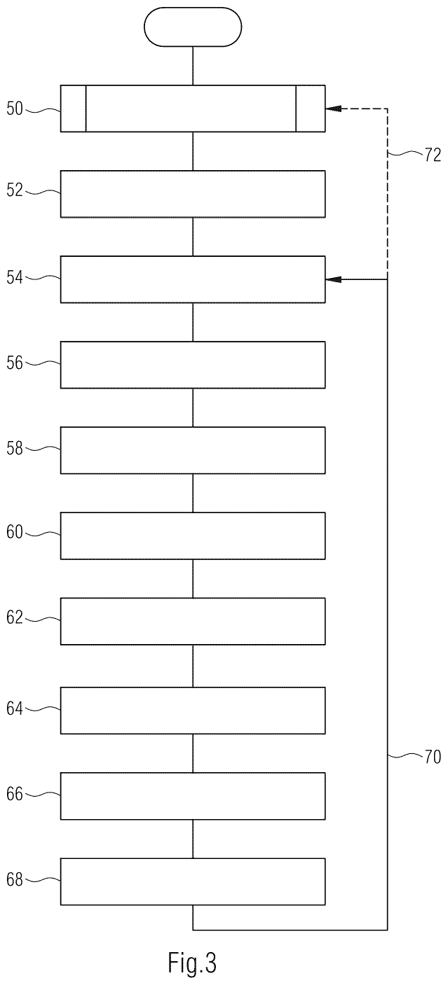

During operation of the apparatus 10, the microprocessor 24, with the aid of the powers obtained from the parallel circulators 30, determines the respective RF signal reflection on the transmission path 18 and, in a manner dependent thereon, varies the operating frequency of the voltage-controlled oscillator 22 in order to reduce the RF signal reflection on the transmission path 18. In this case, the microprocessor 24 can implement the method illustrated in a simplified manner in FIG. 3.

Firstly, in some exemplary embodiments, the optional step 50 can be carried out. Here the available frequency band is scanned sequentially with the aid of an RF test signal, which can be generated by the microprocessor 24 with the aid of the oscillator 22, in order to find an advantageous first operating frequency for heating the medium 12. As an alternative thereto, a nominal first operating frequency can be selected on the basis of theoretical considerations and/or on the basis of practical empirical values.

The RF feed signal having the first operating frequency is then generated in accordance with step 52 and incoupled into the medium in accordance with step 54. In accordance with step 56, a first RF signal reflection on the transmission path 20 is determined. This can be done according to FIG. 1 advantageously using the circulator 30 in each signal path Nx and using the microprocessor 24 or alternatively with the aid of some other, optionally analogous, power measuring device (not illustrated here). In accordance with step 58, the operating frequency of the RF feed signal here is then increased by a defined frequency value fstep during a first test interval and, in accordance with step 60, a second RF signal reflection on the transmission path 20 is determined. The second RF signal reflection temporally correlates with the operating frequency of the RF feed signal increased by fstep. In accordance with step 62, the operating frequency of the RF feed signal here is then reduced by double the defined frequency value fstep during a second test interval, such that the operating frequency of the RF feed signal in the second test interval is reduced by a second frequency value corresponding here to the first frequency value fstep. In accordance with step 64, a third RF signal reflection on the transmission path 20 is determined, which temporally correlates with the reduced operating frequency of the RF feed signal. Step 66 then involves determining which of the three signal reflections obtained was the smallest and, in accordance with step 68, the future operating frequency of the RF feed signal is set to that (second) operating frequency from the triad of “first operating frequency, increased first operating frequency, reduced first operating frequency” which correlates with the smallest signal reflection.

In the preferred exemplary embodiments, in accordance with loop 70, the second operating frequency then set functions as a new first operating frequency, i.e. steps 54 to 68 are cyclically repeated while the RF feed signal is incoupled into the medium.

In some exemplary embodiments, moreover, step 50 can be cyclically repeated in accordance with loop 72, the cycle time of the loop 72 advantageously being chosen to be greater than the cycle time of the loop 70. In particular, the global scan of the frequency band in accordance with step 50 can be repeated with a cycle time amounting to 10 times, 100 times or even 1000 times the cycle time in accordance with loop 70.

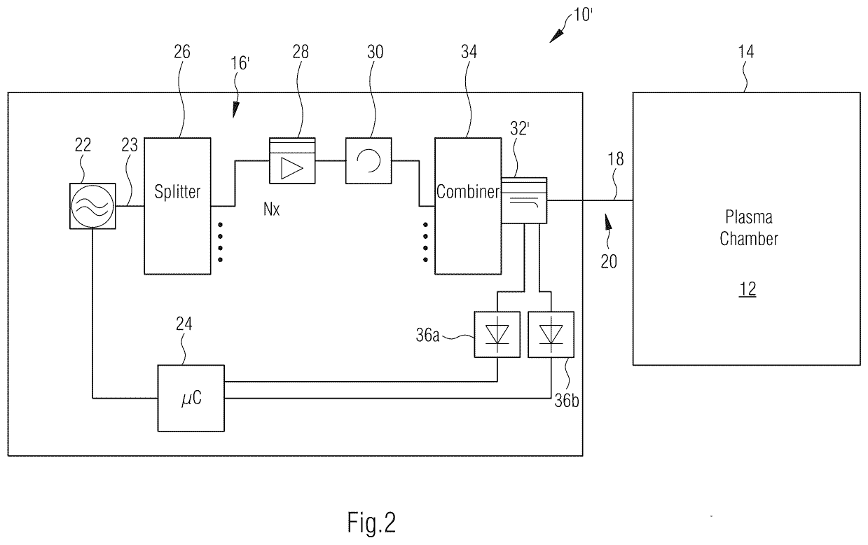

FIG. 2 illustrates a further exemplary embodiment of an apparatus 10′ with which the described method can be advantageously implemented. Identical reference signs designate the same elements as previously.

In the exemplary embodiment in accordance with FIG. 2, a common directional coupler 32′ for a plurality of or all parallel signal paths Nx is arranged at the output of the combiner 34. The directional couplers 32 in the parallel signal paths Nx from FIG. 1 can thus be dispensed with. The directional coupler 32′ is advantageously configured to outcouple both a portion of the outgoing power and a portion of the returning power in order to determine the RF signal reflection. The exemplary embodiment in accordance with FIG. 2 therefore manages with a smaller number of directional couplers. The circulators 30 in the parallel signal paths Nx serve here merely to guide away a remaining signal reflection into a so-called dummy load (not illustrated here). The dummy load is a load that primarily serves to absorb the power of a signal reflection and to convert it into heat (to “annihilate” it).

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for heating a medium by generating a plasma using a radio frequency (RF) signal, the method comprising:
generating a first (RF) feed signal having a defined first operating frequency and a defined first signal power,
incoupling the first RF feed signal into the medium via a transmission path, so that the medium is heated by the first RF feed signal,
determining a first RF signal reflection along the transmission path,
changing the first operating frequency based on the first RF signal reflection in order to reduce temporally succeeding RF signal reflections,
wherein during a first test interval the defined first operating frequency is increased by a defined first frequency value in order to incouple the first RF feed signal into the medium in a temporally limited manner with an increased first operating frequency, and during a second test interval the defined first operating frequency is reduced by a defined second frequency value in order to incouple the first RF feed signal into the medium in a temporally limited manner with a reduced first operating frequency,
determining a second RF signal reflection temporally correlating with the increased first operating frequency during the first test interval,
determining a third RF signal reflection temporally correlating with the reduced first operating frequency during the second test interval, and
after the second test interval has elapsed, generating a second RF feed signal with a defined second operating frequency and incoupling the second RF feed signal into the medium,
wherein the defined second operating frequency is selected based on the first RF signal reflection, the second RF signal reflection, and the third RF signal reflection.

2. The method as claimed in claim 1, further comprising repeating increasing and reducing the first operating frequency cyclically with respective further test intervals, wherein the defined second operating frequency is used as a new first operating frequency after each cycle.

3. The method as claimed in claim 2, wherein the increasing and reducing of the first operating frequency are carried out cyclically with a cycle time that is in a range of 1 ms to 500 ms, inclusive.

4. The method as claimed in claim 1, wherein the first test interval has an interval length that is in a range of 50 μs to 500 μs, inclusive.

5. The method as claimed in claim 1, wherein the defined first operating frequency is increased abruptly by the defined first frequency value at a beginning of the first test interval.

6. The method as claimed in claim 1, wherein the defined first frequency value and the defined second frequency value are equal.

7. The method as claimed in claim 1, wherein the defined first frequency value is in a range of 0.0001% to 0.001% of the defined first operating frequency.

8. The method as claimed in claim 1, wherein the second test interval is directly adjacent to the first test interval.

9. The method as claimed in claim 1, wherein the defined first operating frequency is determined by an RF test signal with an instantaneous operating frequency that passes through a defined frequency band, wherein the RF test signal is transmitted via the transmission path, and RF signal reflections along the transmission path are determined.

10. The method as claimed in claim 9, wherein the RF test signal is generated separately from the RF feed signal and is transmitted via the transmission path.

11. The method as claimed in claim 9, wherein the RF feed signal forms the RF test signal.

12. The method as claimed in claim 9, wherein the RF test signal is generated at a time before the first test interval.

13. The method as claimed in claim 9, wherein the RF test signal is generated again after the second test interval has elapsed.

14. An apparatus for heating a medium by generating a plasma using a radio-frequency (RF) signal, the apparatus comprising
an RF generator configured to generate a first RF feed signal having a defined first operating frequency and a defined first signal power,
a transmission path configured to incouple the first RF feed signal into the medium, such that the medium is heatable by the first RF feed signal, and
a measuring and control device configured to:
determine a first RF signal reflection along the transmission path,
change the first operating frequency based on the first RF signal reflection in order to reduce temporally succeeding RF signal reflections,
increase the defined first operating frequency by a defined first frequency value during a first test interval in order to incouple the first RF feed signal into the medium in a temporally limited manner with an increased first operating frequency,
reduce the defined first operating frequency by a defined second frequency value during a second test interval in order to incouple the first RF feed signal into the medium in a temporally limited manner with a reduced first operating frequency,
during the first test interval, determine a second RF signal reflection temporally correlating with the increased first operating frequency,
during the second test interval, determine a third RF signal reflection temporally correlating with the reduced first operating frequency, and
after the second test interval has elapsed, generate a second RF feed signal with a defined second operating frequency and incouple the second RF feed signal into the medium, wherein the defined second operating frequency is selected based on the first RF signal reflection, the second RF signal reflection, and the third RF signal reflection.
